(19) United States
(12) Patent Application Publication
(10) Pub. No.: US 2024/0360338 A1
(43) Pub. Date: Oct. 31, 2024

(54) POLISHING AGENT, LIQUID ADDITIVE FOR POLISHING AGENT, AND POLISHING METHOD

(71) Applicant: AGC Inc., Tokyo (JP)

(72) Inventor: Hiroka FUKUI, Chiyoda-ku (JP)

(73) Assignee: AGC Inc., Tokyo (JP)

(21) Appl. No.: 18/765,754

(22) Filed: Jul. 8, 2024

Related U.S. Application Data
(63) Continuation of application No. PCT/JP2023/001335, filed on Jan. 18, 2023.

(30) Foreign Application Priority Data
Jan. 28, 2022 (JP) 2022-011486

(51) Int. Cl. C09G 1/02

(52) U.S. Cl. CPC C09G 1/02

(57) ABSTRACT

Provided are a polishing agent and a liquid additive for a polishing agent that provide a high selectivity between a silicon oxide film and a silicon nitride film and that inhibit aggregation of abrasive grains, which can cause polishing-induced scratches, as well as a polishing method that enables high-speed polishing and inhibits polishing-induced scratches. A polishing agent includes an abrasive grain, a water-soluble polymer, and water. The water-soluble polymer is a copolymer of a monomer (A) that is at least one selected from an unsaturated dicarboxylic acid, a derivative thereof, and salts thereof, and a monomer (B) other than the monomer (A). The monomer (B) is a monomer that includes an ethylenic double bond and does not include an acidic group. The water-soluble polymer has an acid value of 200 to 450 mgKOH/g.

### INCORPORATION BY REFERENCE

This application is based upon and claims the benefit of priority from Japanese Patent Application 2022-011486 filed on Jan. 28, 2022, and PCT application No. PCT/JP2023/001335 filed on Jan. 18, 2023, the disclosure of which is incorporated herein in its entirety by reference.

### BACKGROUND

The present invention relates to polishing agents, liquid additives for polishing agents, and polishing methods.

The recent trend toward a higher degree of integration or higher functionality of semiconductor integrated circuits is propelling development in microfabrication technologies that achieve smaller, higher-density semiconductor elements. Conventionally, in the manufacture of semiconductor integrated circuit devices (also referred to below as semiconductor devices), interlayer insulating films, buried wirings, or the like are planarized with the use of chemical mechanical polishing (hereinafter, CMP) so as to prevent such problems as that sufficient resolution cannot be obtained as the unevenness (steps) in a layer surface exceeds the depth of focus in lithography. Importance of higher planarization with the use of CMP is on the rise as the demands for higher-definition, smaller elements become higher.

Furthermore, in the manufacture of semiconductor devices in recent years, a method of isolation with a shallow trench with a small element isolation width (Shallow Trench Isolation: hereinafter, STI) has been adopted in order to advance even higher shrinkage of semiconductor elements.

In this technique called STI, a trench (groove) is formed in a silicon substrate, and the trench is filled with an insulating film; thus, element regions that are electrically insulated are formed. One example of STI will be described with reference to FIGS. 1A and 1B. In the example shown in FIGS. 1A and 1B, as shown in FIG. 1A, an element region of a silicon substrate 1 is masked with a silicon nitride film 2 or the like, a trench 3 is then formed in the silicon substrate 1, and an insulating layer, such as a silicon oxide film 4, is deposited to fill the trench 3. Next, the silicon oxide film 4 on the silicon nitride film 2, which defines a protruding portion, is polished to be removed through CMP, with the silicon oxide film 4 in the trench 3, which defines a recessed portion, retained. Thus, an element isolation structure in which the trench 3 is filled with the silicon oxide film 4, as shown in FIG. 1B, is obtained.

In CMP for STI, adopting a high selectivity between (a high ratio between the polishing rates of) a silicon dioxide film and a silicon nitride film allows the polishing to stop when the silicon nitride film becomes exposed. This polishing method that uses a silicon nitride film as a stopper film in this manner makes it possible to obtain a smoother surface than typical polishing methods. The selectivity described above is required to be higher in recent CMP technologies.

For example, International Patent Publication No. WO2017/043139 discloses, as a technique for curbing the polishing rate of the stopper film above, a specific polishing liquid that contains a polymer having a first molecular chain with a specific functional group directly bonded thereto and a second molecular chain branched from the first molecular chain.

Meanwhile, Japanese Unexamined Patent Application Publication No. 2019-87660 discloses, as a technique for increasing the selectivity between a silicon dioxide film and a silicon nitride film, a polishing agent that contains a specific water-soluble polymer, a cerium oxide particle, and water and that has pH of 4 to 9.

### SUMMARY

The present invention is directed to providing a polishing agent and a liquid additive for a polishing agent that provide a high selectivity between a silicon oxide film and a silicon nitride film and that inhibit aggregation of abrasive grains, which can cause polishing-induced scratches, as well as a polishing method that enables high-speed polishing and inhibits polishing-induced scratches.

A polishing agent according to the present invention includes:
an abrasive grain;
a water-soluble polymer; and
water, wherein
the water-soluble polymer is a copolymer of a monomer (A) that is at least one selected from an unsaturated dicarboxylic acid, a derivative thereof, and salts thereof, and a monomer (B) other than the monomer (A),
the monomer (B) is a monomer that includes an ethylenic double bond and does not include an acidic group, and
the water-soluble polymer has an acid value of 200 to 450 mgKOH/g.

A liquid additive for a polishing agent, according to the present invention, includes:
a water-soluble polymer; and
water, wherein
the water-soluble polymer is a copolymer of a monomer (A) that is at least one selected from an unsaturated dicarboxylic acid, a derivative thereof, and salts thereof, and a monomer (B) other than the monomer (A),
the monomer (B) is a monomer that includes an ethylenic double bond and does not include an acidic group, and
the water-soluble polymer has an acid value of 200 to 450 mgKOH/g.

A polishing method according to the present invention is a polishing method in which a surface to be polished and a polishing pad are brought into contact while a polishing agent is being fed thereto and polishing is performed through relative motions of the surface to be polished and the polishing pad, and the polishing method includes: polishing a surface to be polished that includes a silicon oxide of a semiconductor substrate using the polishing agent according to the present invention as the polishing agent.

The above and other objects, features and advantages of the present disclosure will become more fully understood from the detailed description given hereinbelow which are given by way of illustration only, and thus are not to be considered as limiting the present disclosure.

The present invention provides a polishing agent and a liquid additive for a polishing agent that provide a high selectivity between a silicon oxide film and a silicon nitride film and that inhibit aggregation of abrasive grains as well as a polishing method that enables high-speed polishing and inhibits polishing-induced scratches.

### BRIEF DESCRIPTION OF DRAWINGS

FIG. 1A shows one example of a conventional polishing method and is a sectional view showing a state of a polishing target held before being polished;

FIG. 1B shows one example of the conventional polishing method and is a sectional view showing a state of the polishing target held after being polished; and

FIG. 2 is a schematic diagram showing one example of a polishing apparatus.

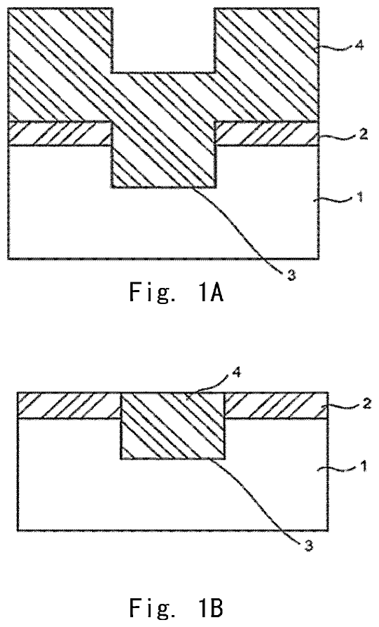

### DESCRIPTION OF EMBODIMENTS

Some embodiments of the present invention will be described below. The present invention is not limited to the following embodiments, and any other embodiments may fall within the scope of the present invention as long as such embodiments fit the spirit of the present invention. The following description and the drawings are simplified as appropriate to make the description clearer. The scales of the members in the drawings may differ to a great extent for the sake of description.

The term “surface to be polished” as used according to the present invention refers to the surface of a polishing target that is to be polished and means, for example, an outer surface. In the present specification, an intermediate-stage surface that appears in a semiconductor substrate in the process of manufacturing semiconductor devices is also encompassed by the “surface to be polished.”

“Silicon oxide” is mainly silicon dioxide but is not limited thereto, and “silicon oxide” may include any silicon oxides other than silicon dioxide.

The term “selectivity” refers to the ratio (RA/RB) of the polishing rate (RA) of a polishing target A (e.g., a silicon oxide film) to the polishing rate (RB) of a stopper film B (e.g., a silicon nitride film).

According to the present invention, something being water-soluble means that 10 mg or more thereof dissolves in 100 g of water at 25° C.

“Meth(acryl)” is a collective term for “methacryl” and “acryl,” and this applies likewise to (meth)acryloyl, (meth)acrylate, and the like.

In addition, the term “to” between numerical values indicating a numerical range means that the numerical values described before and after “to” are included as a lower limit value and an upper limit value in the numerical range.

### [Polishing Agent]

A polishing agent according to the present invention (also referred to below as the present polishing agent) includes an abrasive grain, a water-soluble polymer, and water. The water-soluble polymer is a copolymer of a monomer (A) that is at least one selected from an unsaturated dicarboxylic acid, a derivative thereof, and salts thereof, and a monomer (B) other than the monomer (A). The monomer (B) is a monomer that includes an ethylenic double bond and does not include an acidic group. The water-soluble polymer has an acid value of 200 to 450 mgKOH/g.

When the present polishing agent is used, for example, in CMP of a surface to be polished that includes a silicon oxide film (e.g., a silicon dioxide film) in STI, polishing of a silicon nitride film can be limited while achieving a high polishing rate of the silicon oxide film with polishing-induced scratches being inhibited, and a high selectivity between the silicon oxide film and the silicon nitride film can obtained. Hence, polishing yielding high planarity can be achieved.

Although the mechanism by which the present polishing agent exhibits the effects described above is still in part unclear, it is speculated that the effects above are because the specific water-soluble polymer becomes adsorbed onto both the surface to be polished (the silicon nitride surface, in particular) and the abrasive grains. A carboxy group of the water-soluble polymer, a derivative thereof, and salts thereof (may also be referred to below as a carboxy group and so on) are susceptible to being adsorbed onto a silicon nitride surface, and polishing of the silicon nitride surface becomes limited by the water-soluble polymer adsorbed thereon. In particular, using a water-soluble polymer having an acid value of 450 mgKOH/g or lower increases the selectivity between a silicon nitride and a silicon oxide. Meanwhile, the water-soluble polymer adsorbed onto the abrasive grains inhibits aggregation of the abrasive grains and reduces the occurrence of coarse particles. In particular, using a water-soluble polymer having an acid value of 200 mgKOH/g or higher makes the water-soluble polymer more susceptible to being adsorbed onto the abrasive grains and increases the solubility of the water-soluble polymer. Hence, aggregation within the water-soluble polymer is also inhibited.

The present polishing agent contains at least an abrasive grain, a water-soluble polymer, and water, and may further contain another component within a range in which the advantageous effects of the present invention are obtained. Each of the components that can be included in the present polishing agent will be described below.

### <Abrasive Grain>

For the present polishing agent, an abrasive grain to be used can be selected, as appropriate, from among abrasive grains for use in CMP. Examples of the abrasive grain includes at least one selected from the group consisting of a silica particle, an alumina particle, a zirconia particle, a cerium compound particle (e.g., a ceria particle, a cerium hydroxide particle), a titania particle, a germania particle, and a core-shell particle having any of the above as a core particle. Examples of the silica particle above include colloidal silica and fumed silica. For the alumina particle above, colloidal alumina can be used.

The core-shell particle above is composed of a core particle (e.g., a silica particle, an alumina particle, a zirconia particle, a cerium compound particle, a titania particle, or a germania particle) and a thin film covering the surface of the core particle.

Examples of materials for the thin film above include at least one selected from oxides such as silica, alumina, zirconia, ceria, titania, germania, an iron oxide, a manganese oxide, a zinc oxide, a yttrium oxide, a calcium oxide, a magnesium oxide, a lanthanum oxide, and a strontium oxide. Furthermore, the thin film above may be formed of a plurality of nanoparticles consisting of any of the oxides above.

The core particle above has a particle size of preferably 0.01 to 0.5 μm or more preferably 0.03 to 0.3 μm.

It suffices that the particle size of the nanoparticles above be smaller than the particle size of the core particle above, and the nanoparticles have a particle size of preferably 1 to 100 nm or more preferably 5 to 80 nm.

As to the abrasive grain, among those mentioned above, a silica particle, an alumina particle, or a cerium compound particle is preferable, and a cerium compound particle is more preferable, from the standpoint of superiority in the polishing rate of an insulating film; and when the surface to be polished includes an insulating film (in particular, a silicon oxide film), a ceria particle is even more preferably from the standpoint of a higher polishing rate being obtained. In the case of a core-shell particle, it is preferable that the thin film include silica, alumina, or a cerium compound, and it is more preferable that the thin film include ceria. These kinds of abrasive grains can each be used alone, or two or more kinds of these abrasive grains can be used in combination.

The ceria content with respect to the total mass of the abrasive grains is preferably 70 mass % or higher, more preferably 80 mass % or higher, even more preferably 90 mass % or higher, particularly preferably 95 mass % or higher, or most preferably 100 mass %. When the ceria content with respect to the total mass of the abrasive grains is 70 mass % or higher, this makes it easier to raise the polishing rate of, in particular, an insulating film.

The ceria particle to use can be selected, as appropriate, from those known, and examples include a ceria particle manufactured through a method described in Japanese Unexamined Patent Application Publication No. H11-12561, Japanese Unexamined Patent Application Publication No. 2001-35818, or Published Japanese Translation of PCT International Publication for Patent Application, No. 2010-505735. Specific examples include a ceria particle obtained by fabricating a cerium hydroxide gel by adding alkali to a cerium (IV) nitrate ammonium aqueous solution and filtering, washing, and sintering the fabricated cerium hydroxide gel; a ceria particle obtained by sintering a high-purity cerium carbonate upon pulverizing it and further pulverizing and classifying the resultant; and a ceria particle obtained by chemically oxidizing a cerium (III) salt in liquid.

Although a ceria particle may include impurity other than ceria, the ceria content in a single ceria particle is preferably 80 mass % or higher, more preferably 90 mass % or higher, even more preferably 95 mass % or higher, or most preferably 100 mass % (free of impurity). When the ceria content in a ceria particle is 80 mass % or higher, this makes it easier to improve the polishing rate of an insulating film.

The mean particle size of the abrasive grains is preferably 0.01 to 0.5 μm or more preferably 0.03 to 0.3 μm. When the mean particle size is 0.5 μm or lower, this reduces the mechanical action on the surface to be polished and thus reduces the occurrence of polishing-induced scratches, such as scratches, produced in the surface to be polished. Meanwhile, when the mean particle size is 0.01 μm or higher, this inhibits aggregation of the abrasive grains to provide the polishing agent with excellent storage stability and an excellent polishing rate.

The abrasive grains are present, in liquid, in the form of aggregated particles (secondary particles) in which primary particles are aggregated, and thus the mean particle size described above is the mean secondary particle size. The mean secondary particle size is measured by a particle size distribution meter of a laser diffraction/scattering system or the like with the use of a dispersion in which the particles are dispersed in a dispersion medium, such as pure water.

The abrasive grain content described above with respect to the total mass of the polishing agent is preferably 0.01 to 10.0 mass %, more preferably 0.05 to 2.0 mass %, even more preferably 0.1 to 1.5 mass %, or particularly preferably 0.15 to 1.0 mass %. When the abrasive grain content ratio is at the above lower limits or higher, an excellent polishing rate of the surface to be polished is obtained. Meanwhile, when the abrasive grain content ratio is at the above upper limits or lower, aggregation of the abrasive grains can be inhibited, and a rise in the viscosity of the present polishing agent can be curbed, leading to high ease of handling.

### <Water-Soluble Polymer>

In the present polishing agent, the water-soluble polymer is a copolymer of a monomer (A) that is at least one selected from an unsaturated dicarboxylic acid, a derivative thereof, and salts thereof, and a monomer (B) that is a monomer other than the monomer (A) and that includes an ethylenic double bond and does not include an acidic group, and the water-soluble polymer has an acid value of 200 to 450 mgKOH/g. Using the specific water-soluble polymer above makes it possible to obtain a high selectivity between a silicon oxide film and a silicon nitride film while inhibiting polishing-induced scratches. The water-soluble polymer includes at least a structural unit derived from the monomer (A) and a structural unit derived from the monomer (B), and may further include another structural unit within a range in which the advantageous effects of the present invention are obtained.

### (Monomer (A))

The monomer (A) is composed of one or more selected from an unsaturated dicarboxylic acid, a derivative of the unsaturated dicarboxylic acid, a salt of the unsaturated dicarboxylic acid, and a salt of the derivative of the unsaturated dicarboxylic acid. This monomer (A) contributes to the adsorption of the water-soluble polymer onto the abrasive grains or a silicon nitride surface and also regulates the acid value of the water-soluble polymer.

The unsaturated dicarboxylic acid in the monomer (A) may be a compound having two carboxy groups in a single molecule and an ethylenic double bond. The two carboxy groups may be, for example, an acid anhydride, like a maleic anhydride. In the use mode of the present polishing agent, acid anhydrides in the water-soluble polymer are normally hydrolyzed.

The unsaturated dicarboxylic acid may have a ring structure or may be an open-chain compound that does not have a ring structure, but is preferably an open-chain compound from the standpoint of adsorptivity onto the surface to be polished.

It suffices that there be one or more ethylenic double bonds, and the number of ethylenic double bonds is preferably 1 to 2 or more preferably 1.

Specific examples of the unsaturated dicarboxylic acid include malonic acid, fumaric acid, itaconic acid, citraconic acid, mesaconic acid, 2-allylmalonic acid, and isopropylidenesuccinic acid, and among these, from the standpoint of polymericity, maleic acid, itaconic acid, or fumaric acid is preferable, or maleic acid is more preferable. An unsaturated dicarboxylic acid can be used alone, or two or more unsaturated dicarboxylic acids can be used in combination.

A salt of an unsaturated dicarboxylic acid refers to a compound in which at least one of the two carboxy groups of the unsaturated dicarboxylic acid is a salt. A salt of an unsaturated dicarboxylic acid includes not only one that has undergone salt formation while being a monomer but also one that has undergone salt formation after copolymerizing the unsaturated dicarboxylic acid.

Examples of a carboxylic acid salt (also referred to as COO⁻) include an alkali metal salt and an ammonium salt. Specific examples include a sodium salt, a potassium salt, an ammonium salt, a monoethanol ammonium salt, a diethanol ammonium salt, and a triethanol ammonium salt, and from the standpoint of obviating the need to consider the mixing of metal impurity, an ammonium salt is preferable.

A derivative of an unsaturated dicarboxylic acid is a compound in which at least one of the two carboxy groups of the unsaturated dicarboxylic acid is derivatized. A derivative of an unsaturated dicarboxylic acid includes not only one derivatized while being a monomer but also one derivatized (e.g., esterified) after copolymerizing the unsaturated dicarboxylic acid. The derivatization may be resolved after copolymerization, and for example, the ester may be hydrolyzed after copolymerization.

Examples of the derivatized carboxy group (also referred to as COR, wherein R is a substituent) include an ester (C(═O)OR¹, wherein R¹ is an organic group) and an amide (C(═O)NR²R³, wherein R² and R³ are each independently a hydrogen atom or an organic group).

The organic group in R¹ may have a substituent and is preferably a saturated hydrocarbon group that may have an oxygen atom in a carbon-carbon bond. The saturated hydrocarbon group may be linear or be branched or have a ring structure. Examples of the substituent that may be included in the saturated hydrocarbon group include a hydroxyl group and a halogen atom. Examples of the saturated hydrocarbon group having an oxygen atom in a carbon-carbon bond include an alkylene oxide (—(R¹¹O)ₙH, wherein R¹¹ is an alkylene group with a carbon number of 1 to 6, n is an integer greater than or equal to 1 and is preferably an integer in a range of 1 to 50), such as an ethylene oxide or a propylene oxide. The carbon number in R¹ is preferably 1 to 50, more preferably 2 to 30, or even more preferably 5 to 20.

R² and R³ are each independently a hydrogen atom or an organic group. When R² or R³ is an organic group, examples of that organic group include those similar to the ones listed for R¹, and preferred modes are also similar.

The two carboxylic acids in a derivative of an unsaturated dicarboxylic acid may be derivatives identical to each other or different from each other. Only one of the two carboxy groups may be derivatized.

Examples of the derivative of the unsaturated dicarboxylic acid include an unsaturated dicarboxylic acid monoester, an unsaturated dicarboxylic acid diester, an unsaturated dicarboxylic acid monoamide, and an unsaturated dicarboxylic acid diamide. From the standpoint of the adsorptivity onto the surface to be polished, the derivative of the unsaturated dicarboxylic acid preferably includes, among the above, an unsaturated dicarboxylic acid monoester or an unsaturated dicarboxylic acid diester.

A salt of a derivative of an unsaturated dicarboxylic acid is a compound in which one of the unsaturated dicarboxylic acids has been derivatized into a derivative and the other has undergone salt formation. The salt of the derivative of the unsaturated dicarboxylic acid includes not only one that has been derivatized and/or has undergone salt formation while being a monomer but also one that has been derivatized and/or has undergone salt formation after copolymerizing the unsaturated dicarboxylic acid. The derivative and the salt of the carboxylic acid in the salt of the derivative of the unsaturated dicarboxylic acid is as described above, and preferred modes are also similar. Particularly among the above, a salt of an unsaturated dicarboxylic acid monoester is preferable.

The monomer (A) is composed of one or more selected from an unsaturated dicarboxylic acid, a derivative of the unsaturated dicarboxylic acid, a salt of the unsaturated dicarboxylic acid, and a salt of the derivative of the unsaturated dicarboxylic acid. When the monomer (A) includes two or more of the above, such a combination may be, for example, a combination of two or more in which the types of the unsaturated dicarboxylic acids differ from each other or, for example, a combination of one or more types of unsaturated dicarboxylic acids and a derivative and/or a salt of one or more types of unsaturated dicarboxylic acids.

From the standpoint of adsorption of the water-soluble polymer onto the abrasive grains or a silicon nitride surface, the monomer (A) preferably includes, among the above, one or more selected from an unsaturated dicarboxylic acid and a salt of an unsaturated dicarboxylic acid.

### (Monomer (B))

The monomer (B) is a compound that is other than the monomer (A) and that includes an ethylenic double bond and does not include an acidic group. This monomer (B) contributes to inhibiting aggregation of abrasive grains or curbing the polishing rate of a silicon nitride surface and also regulates the acid value of the water-soluble polymer.

It suffices that there be one or more ethylenic double bonds in a single molecule of the monomer (B), and the number of ethylenic double bonds is preferably 1 to 2 or more preferably 1. For the monomer (B), one type alone can be selected for use from monomers having no acidic group, or two or more types may be selected for use from the above.

The monomer (B) may be a monomer that has a ring structure or a monomer that does not have a ring structure. From the standpoint of inhibiting aggregation of abrasive grains or curbing the polishing rate of a silicon nitride surface, the monomer (B) preferably includes a monomer having a ring structure.

Examples of the monomer having a ring structure include a monocyclic olefin, such as cyclobutene, cyclopentene, cyclohexene, cycloheptene, or cyclooctene, and derivatives thereof;
a cyclic conjugated diene, such as cyclopentadiene, cyclohexadiene, cycloheptadiene, or cyclooctadiene, and derivatives thereof;
a polycyclic olefin, such as norbornene, dicyclopentadiene, tricyclodecene, tetracyclododecene, or hexacycloheptadecene, and derivatives thereof;
a vinyl alicyclic hydrocarbon, such as vinyl cyclobutane, vinyl cyclobutene, vinyl cyclopentane, vinyl cyclopentene, vinyl cyclohexane, vinyl cyclohexene, vinyl cycloheptane, vinyl cycloheptene, vinyl cyclooctane, vinyl cyclooctene, N-vinylpyrrolidone, N-vinylcarbazole, or 4-vinylpyridine, and derivatives thereof; and
a vinyl aromatic monomer, such as styrene, methylstyrene, vinyltoluene, p-t-butylstyrene, chloromethylstyrene, o-(or p-, m-)hydroxystyrene, or o-(or p-, m-)hydroxyphenyl acrylate, and derivatives thereof.

Meanwhile, examples of the monomer that does not have a ring structure include an olefin, such as ethylene, propylene, butene, pentene, hexene, heptene, octene, nonene, decene, isopropylene, isobutene, isopentene, isohexene, isoheptene, isooctene, isononene, or isodecene, and derivatives thereof;
an aliphatic conjugated diene, such as butadiene, 1,3-butadiene, isoprene, 2,3-dimethyl-1,3-butadiene, or 1,3-pentadinene, and derivatives thereof;
a (meth)acrylic ester, such as methyl (meth)acrylate, ethyl (meth)acrylate, propyl (meth)acrylate, n-amyl (meth)acrylate, isoamyl (meth)acrylate, n-hexyl (meth)acrylate, 2-ethylhexyl (meth)acrylate, n-octyl (meth)acrylate, 2-hydroxyethyl (meth)acrylate, or hydroxypropyl (meth)acrylate, and derivatives thereof;
an ethylenic unsaturated carboxylic acid hydroxyalkyl ester, such as β-hydroxyethyl acrylate, β-hydroxypropyl acrylate, or β-hydroxyethyl methacrylate, and derivatives thereof;
an unsaturated carboxylic acid glycidyl ester, such as glycidyl acrylate or glycidyl methacrylate, and derivatives thereof; a vinyl compound, such as acrolein or allylalcohol, and derivatives thereof;
an ethylenic unsaturated nitrile, such as acrylonitrile or methacrylonitrile, and derivatives thereof; and
an ethylenic unsaturated carboxylic acid amide, such as acrylamide, methacrylamide, N-methylolacrylamide, or diacetoneacrylamide, and derivatives thereof.

From the standpoint of inhibiting aggregation of abrasive grains and curbing the polishing rate of a silicon nitride surface, the monomer (B) includes, among the above, preferably a compound including a 5-membered ring or a 6-membered ring and an olefin with a carbon number of 3 to 7, more preferably styrene, N-vinylpyrrolidone, 4-vinylpyridine, or isobutylene, or even more preferably styrene or isobutylene. When the monomer (B) is composed of any of the above, the water-soluble polymer described later has a favorable hydrophobicity, and the selectivity further improves.

### (Other Monomers)

The water-soluble polymer may further include another monomer within a range in which the advantageous effects of the present invention are obtained. Example of the other monomer include an unsaturated monocarboxylic acid, such as acrylic acid or methacrylic acid. The proportion of the other monomer with respect to the total amount of the monomers composing the water-soluble polymer is preferably 10 mol % or lower, more preferably 5 mol % or lower, or even more preferably 1 mol % or lower.

### (Other Characteristics of Water-Soluble Polymer)

When each of the monomers described above is a monofunctional monomer with a single ethylenic double bond, a chain water-soluble polymer is obtained. Such a water-soluble polymer may be a random copolymer in which the monomer (A) and the monomer (B) are bonded randomly, or a block copolymer in which the monomer (A) and the monomer (B) each form one or more blocks.

The adsorptivity of the water-soluble polymer onto a silicon nitride surface and the abrasive grains can be evaluated through the following formula (1).

$$X = ( the number of COOH and {COO}^{-} in the water - soluble polymer above ) / ( the number of COOH , {COO}^{-} and COR in the water - soluble polymer above ) \qquad ( 1 )$$

X designates the value representing the proportion of those that are not derivatized to the structures derived from a carboxy group present in the water-soluble polymer. Here, as compared with a carboxylic acid derivative (COR), a carboxy group (COOH) and carboxylic acid salt (COO⁻) tends to excel in the adsorptivity onto a silicon nitride surface and the abrasive grains due to the hydrophilic interaction or electrostatic interaction. Accordingly, as X is greater, the adsorptivity of the water-soluble polymer onto a silicon nitride surface and the abrasive grains tends to be higher.

When the water-soluble polymer is adsorbed onto a silicon nitride surface, a protection film is formed on the silicon nitride surface, and the polishing of the silicon nitride surface by the abrasive grains is limited. Therefore, a high selectivity can be obtained.

When the water-soluble polymer becomes adsorbed onto the abrasive grains, the dispersiveness of the abrasive grains improves mainly due to the steric hindrance. When the dispersiveness of the abrasive grains is high, the occurrence of coarse particles in which the abrasive grains have aggregated is inhibited, and thus polishing-induced scratches are less likely to occur.

From such standpoints above, it is preferable that X be large. Specifically, X is preferably 0.5 or higher, more preferably 0.55 or higher, even more preferably 0.6 or higher, even further more preferably 0.65 or higher, particularly preferably 0.7 or higher, extremely preferably 0.75 or higher, or most preferably 0.8 or higher. Herein, the upper limit of X is 1.

The value of X is calculated, for example, from the amount of monomers charged in the synthesis of the water-soluble polymer. In another example, the value of X can be obtained from the peak area in the ¹³C-NMR measurement result.

Herein, the value of X can be adjusted by selecting monomers as appropriate or by derivatizing or resolving such derivatization after copolymerization when the monomers are copolymerized to obtain the water-soluble polymer.

The mole ratio of the monomer (A) composing the water-soluble polymer with respect to the total amount of the monomers is preferably mol % or higher or more preferably 10 mol % or higher. When the mole ratio of the monomer (A) is 5 mol % or higher, the water-soluble polymer has COOH and COO⁻ at a sufficient level, and the adsorptivity of the water-soluble polymer onto a silicon nitride surface and the abrasive grains improves.

The mole ratio of the monomer (A) composing the water-soluble polymer with respect to the total amount of the monomers is preferably 70 mol % or lower, more preferably 60 mol % or lower, even more preferably 50 mol % or lower, particularly preferably 40 mol % or lower, or extremely preferably 35 mol % or lower. When the mole ratio of the monomer (A) is 70 mol % or lower, the water-soluble polymer has the monomer (B) at a sufficient level, and the water-soluble polymer has a high hydrophobicity. A protection film formed by the water-soluble polymer adsorbed onto a silicon nitride surface is less likely to attract the abrasive grains as the hydrophobicity of the water-soluble polymer is higher, and thus the selectivity further improves.

The acid value of the water-soluble polymer tends to be dependent on X and the mole ratio of the monomer (A) described above. In other words, the acid value tends to have a higher value as X is greater and/or as the mole ratio of the monomer (A) is higher.

The acid value of the water-soluble polymer is preferably 200 mgKOH/g or higher, more preferably 230 mgKOH/g or higher, or even more preferably 250 mgKOH/g or higher. When the acid value of the water-soluble polymer is 200 mgKOH/g or higher, at least one of X or the mole ratio of the monomer (A) becomes sufficiently large, and the adsorptivity of the water-soluble polymer onto a silicon nitride surface or the abrasive grains improves. Furthermore, when the acid value of the water-soluble polymer is 200 mgKOH/g or higher, the solubility of the water-soluble polymer in water improves, and aggregation in the water-soluble polymer is inhibited.

The acid value of the water-soluble polymer is preferably 450 mgKOH/g or lower, more preferably 420 mgKOH/g or lower, or even more preferably 400 mgKOH/g or lower. When the acid value of the water-soluble polymer is 450 mgKOH/g or lower, the mole ratio of the monomer (A) is kept at or below a predefined value, and thus the selectivity further improves, as described above.

Herein, the acid value represents the mass (mg) of potassium hydroxide required to neutralize the acid component included in 1 g of solid content of the polymer, and is a value measured through the method described in JIS K 0070:1992.

The weight-average molecular weight of the water-soluble polymer may be adjusted, as appropriate, within a range of, for example, 100,000 or lower. The weight-average molecular weight is preferably 500 or higher, more preferably 1,000 or higher, or even more preferably 5,000 or higher. When the weight-average molecular weight is 500 or higher, the adsorptivity of the water-soluble polymer described above becomes sufficient. Meanwhile, the weight-average molecular weight is preferably 50,000 or lower, more preferably 40,000 or lower, even more preferably 30,000 or lower, particularly preferably 20,000 or lower, extremely preferably 15,000 or lower, or most preferably 10,000 or lower. When the weight-average molecular weight is 50,000 or lower, aggregation in the water-soluble polymer is inhibited.

Herein, the weight-average molecular weight is a value by polystyrene equivalent measured through gel permeation chromatography (GPC).

From the standpoint that a high polishing rate of a silicon oxide film is obtained and a higher selectivity is obtained, the water-soluble polymer content ratio (concentration) in the present polishing agent with respect to the total mass of the polishing agent is preferably 0.001 to 10.0 mass %, more preferably 0.01 to 5.0 mass %, or even more preferably 0.01 to 2.0 mass %.

### (Method of Manufacturing Water-Soluble Polymer)

The method of manufacturing the water-soluble polymer may be selected, as appropriate, from known methods of polymerization. For example, in the case of a random copolymer, the monomer (A), the monomer (B), and another monomer, if necessary, are mixed, an initiator is added thereto, and the resultant can be polymerized through a known method of polymerization, such as solution polymerization, bulk polymerization, or various radical polymerization techniques. From the standpoint of ease of adjusting the weight-average molecular weight of the copolymer, solution polymerization is preferable among the above.

### <Water>

The present polishing agent contains water as a medium for dispersing abrasive grains (A) and a metallic salt (B). Although there is no particular limitation on the type of the water, preferably, pure water, ultrapure water, ion exchanged water, or the like is used in consideration of the effect on the water-soluble polymer and so on, the prevention of mixing of impurity, or the effect on the pH or the like.

### <Other Components>

The present polishing agent may further contain another component within a range in which the advantageous effects of the present invention are obtained. Examples of such other components include a pH regulator, an aggregation inhibitor, a dispersant, a lubricant, a viscosity adder, a viscosity regulator, and a preservative.

### (pH Regulator)

To attain a pH of a predetermined value, the present polishing agent may contain a pH regulator. The pH regulator to use can be selected, as appropriate, from amphoteric compounds, such as an acid compound, a basic compound, and an amino acid, as well as salts thereof. The present polishing agent preferably includes, as a pH regulator, an acid (an acid compound). Examples of the acid include an inorganic acid, an organic acid, or salts thereof. Examples of the inorganic acid include nitric acid, sulfuric acid, and hydrochloric acid, and an ammonium salt, a sodium salt, a potassium salt, or the like thereof may be used.

Examples of the organic acid include a compound having a carboxy group, a sulfo group, or a phospho group as an acidic group as well as an ammonium salt, a sodium salt, a potassium salt, or the like thereof, and among the above, an organic acid having 1 to 2 carboxy groups in one molecule is preferable. These pH regulators can each be used alone, or two or more of these pH regulators can be used in combination.

Examples of the organic acid having a carboxy group include an alkyl monocarboxylic acid, such as formic acid, acetic acid, or propionic acid;
a carboxylic acid having a heterocycle, such as 2-pyridine carboxylic acid, 3-pyridine carboxylic acid, 4-pyridine carboxylic acid, 2,3-pyridine dicarboxylic acid, 2,4-pyridine dicarboxylic acid, 2,5-pyridine dicarboxylic acid, 2,6-pyridine dicarboxylic acid, 3,4-pyridine dicarboxylic acid, 3,5-pyridine dicarboxylic acid, pyrazine carboxylic acid, 2,3-pyrazine dicarboxylic acid, 2-quinoline carboxylic acid, pyroglutamic acid, picolinic acid, DL-pipecolic acid, 2-furan carboxylic acid, 3-furan carboxylic acid, tetrahydrofuran-2-carboxylic acid, or tetrahydrofuran-2,3,4,5-tetracarboxylic acid;
a carboxylic acid having an alicycle, such as cyclopentane carboxylic acid, cyclohexane carboxylic acid, cycloheptane carboxylic acid, or cyclohexyl carboxylic acid;
a carboxylic acid having an amino group, such as alanine, glycine, glycylglycine, aminobutyric acid, N-acetylglycine, N,N-di(2-hydroxyethyl)glycine, N-(tert-butoxycarbonyl)glycine, proline, trans-4-hydroxy-L-proline, phenylalanine, sarcosine, hydantoic acid, creatine, N-[tris(hydroxymethyl)methyl]glycine, glutamic acid, or aspartic acid;
a carboxylic acid having a hydroxyl group, such as lactic acid, malic acid, citric acid, tartaric acid, glycolic acid, gluconic acid, salicylic acid, 2-hydroxyisobutyric acid, glyceric acid, 2,2-bis(hydroxymethyl)propionic acid, or 2,2-bis(hydroxymethyl)butyric acid;
a carboxylic acid having a ketone group (keto acid), such as pyruvic acid, acetoacetic acid, or levulinic acid; and
oxalic acid, malonic acid, succinic acid, fumaric acid, maleic acid, glutaric acid, adipic acid, and phthalic acid.

The organic acid described above to be included is, among the above, preferably one or more selected from acetic acid, gluconic acid, lactic acid, picolinic acid, malic acid, oxalic acid, succinic acid, adipic acid, maleic acid, 2-hydroxyisobutyric acid, 2-bis(hydroxymethyl)propionic acid, and 2-bis(hydroxymethyl)butyric acid, or more preferably one or more selected from picolinic acid, succinic acid, adipic acid, maleic acid, 2-hydroxyisobutyric acid, 2-bis(hydroxymethyl)propionic acid, and 2-bis(hydroxymethyl)butyric acid. When any of these organic acids is used as a pH regulator, a high polishing rate of a silicon oxide film can be achieved, and a high selectivity between a silicon oxide film and a silicon nitride film can be obtained. Although the mechanism by which such effects are obtained is still in part unclear, it is inferred that using any of these organic acids and the water-soluble polymer according to the present invention in combination increases the interaction between the abrasive grains and a silicon oxide film and makes the water-soluble polymer more easily be adsorbed onto a silicon nitride film, and thus a protection film is formed favorably.

A basic compound may be contained as a pH regulator. Examples of the basic compound include ammonium, potassium hydroxide; a quaternary ammonium hydroxide, such as tetramethylammonium hydroxide or tetraethylammonium hydroxide; and an organic amine, such as monoethanol amine or ethylene diamine.

The present polishing agent preferably has a pH of 5 to 8. When the pH is 8 or lower, the polishing rate of a silicon nitride film is further curbed, and the selectivity further improves. Meanwhile, when the pH is 5 or higher, the polishing rate of a silicon oxide film further improves, and the selectivity further improves. In particular, the present polishing agent more preferably has a pH of 5.2 to 7.8. The pH regulator content ratio may be adjusted as appropriate to obtain the pH mentioned above. In one example, the content ratio with respect to the entirety of the present polishing agent can be set to 0.005 to 2.0 mass %, and is preferably 0.01 to 1.5 mass % or more preferably 0.01 to 0.3 mass %.

A dispersant is used to stably disperse the abrasive grains in a dispersion medium, and example of the dispersant include an anionic, a cationic, a nonionic, or an amphoteric surfactant.

A lubricant is used, as necessary, to improve the lubricity of the polishing agent and to improve the within-surface uniformity of the polishing rate, and examples of the lubricant include a water-soluble polymer, such as polyethylene glycol or polyglycerin.

The method of preparing the present polishing agent may be selected, as appropriate, from the methods that allow abrasive grains, a water-soluble polymer, and each component used as necessary to be dispersed or dissolved uniformly in water serving as a medium.

For example, preferably, a dispersion of the abrasive grains and an aqueous solution of the water-soluble polymer (also referred to as a liquid additive for polishing) are each prepared, and these are mixed together to prepare the present polishing agent. According to this method, excellent storage stability of the dispersion and the liquid additive for polishing above or excellent ease of transport can be obtained.

Preferably, the present polishing agent is prepared in use by performing the mixing described above in a polishing apparatus.

### [Liquid Additive for Polishing]

A liquid additive for polishing according to the present invention is a liquid additive for preparing a polishing agent by being mixed with a dispersion of the abrasive grains described above, and the liquid additive for polishing includes a water-soluble polymer and water. The water-soluble polymer is a copolymer of a monomer (A) that is at least one selected from an unsaturated dicarboxylic acid, a derivative thereof, and salts thereof, and a monomer (B) other than the monomer (A). The monomer (B) is a monomer that includes an ethylenic double bond and does not include an acidic group. The water-soluble polymer has an acid value of 200 to 450 mgKOH/g.

As the liquid additive for polishing above is added to the dispersion of abrasive grains, a polishing agent that can keep the polishing rate of a silicon nitride film low while retaining a high polishing rate of a silicon oxide film and that can achieve high selectivity and planarity can be obtained.

The liquid additive for polishing above includes at least a water-soluble polymer and water and may further include, as necessary, for example, a pH regulator, an aggregation inhibitor, a dispersant, a lubricant, a viscosity adder, a viscosity regulator, or a preservative. These components are as described above, and thus description thereof will be omitted here.

Herein, when a polishing agent is prepared by having two separate liquids of a dispersion of abrasive grains and a liquid additive for polishing and by mixing these liquids, the concentration of cerium oxide particles in the dispersion and the concentration of the water-soluble polymer in the liquid additive for polishing can be condensed to 2 to 100 times the concentrations to be held when the polishing agent is used, and the dispersion and the liquid additive can each be diluted to a predetermined concentration when used. To be more specific, when, for example, the concentration of the cerium oxide particles in the dispersion and the concentration of the water-soluble polymer in the liquid additive are both condensed to 10 times, 10 parts by mass of the dispersion, 10 parts by mass of the liquid additive for polishing, and 80 parts by mass of water are mixed and stirred to yield the polishing agent.

In the liquid additive for polishing described above, the water-soluble polymer content ratio (concentration) with respect to the entirety of the liquid additive is preferably 0.001 to 30 mass %, more preferably 0.01 to 20 mass %, or even more preferably 0.1 to 10 mass %. Meanwhile, the abrasive grain content ratio in the dispersion of the abrasive grains is preferably 0.2 to 40 mass %, more preferably 1 to mass %, or even more preferably 5 to 10 mass %.

### [Polishing Method]

A polishing method according to the present is a polishing method in which a surface to be polished and a polishing pad are brought into contact while a polishing agent is being fed thereto and polishing is performed through the relative motions of the surface to be polished and the polishing pad, and the polishing method includes polishing a surface to be polished that includes a silicon oxide of a semiconductor substrate using the polishing agent according to the present invention described above as the polishing agent.

Here, examples of the surface to be polished include a surface including a surface composed of silicon dioxide of a semiconductor substrate, a blanket wafer in which a silicon nitride film and a silicon oxide film are layered on top of each other on a surface of a semiconductor substrate, and a patterned wafer in which these types of films are arranged in a pattern. Preferred examples of the semiconductor substrate include a substrate for STI. The polishing agent according to the present invention works effectively also in polishing for planarization of an interlayer insulating film in multilayer wiring in the manufacture of a semiconductor device.

Examples of the silicon oxide film in an STI substrate include what is known as a PE-TEOS film, which is deposited through a plasma CVD technique with tetraethoxysilane (TEOS) used as a source material. Other examples of the silicon oxide film include what is known as an HDP film, which is deposited through a high-density plasma CVD technique. A HARP film or an FCVD film deposited through other CVD techniques or an SOD film formed through spin coating can also be used. Examples of the silicon nitride film include a film deposited through a low-pressure CVD technique or a plasma CVD technique or a film deposited through an ALD technique, with silane or dichlorosilane and ammonia used as source materials.

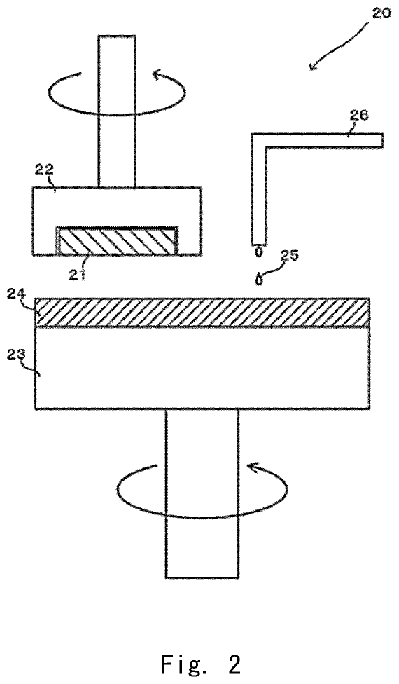

A known polishing apparatus can be used in the present polishing method. FIG. 2 is a schematic diagram showing one example of a polishing apparatus. A polishing apparatus 20 of the example shown in FIG. 2 includes a polishing head 22 that holds a semiconductor substrate 21, such as an STI substrate; a polishing platen 23; a polishing pad 24 affixed to a surface of the polishing platen 23; and a polishing agent feeding pipe 26 that feeds a polishing agent 25 to the polishing pad 24. While the polishing agent 25 is fed from the polishing agent feeding pipe 26, a surface to be polished of the semiconductor substrate 21 held by the polishing head 22 is brought into contact with the polishing pad 24, and the surface to be polished is polished with the polishing head 22 and the polishing platen 23 each undergoing a rotary motion relative to each other.

The polishing head 22 may undergo not only a rotary motion but also a linear motion. The polishing platen 23 and the polishing pad 24 may have a size equivalent to or smaller than the size of the semiconductor substrate 21. In this case, it is preferable that the polishing head 22 and the polishing platen 23 be moved relative to each other, so that the entire surface of the surface to be polished of the semiconductor substrate 21 can be polished. The polishing platen 23 and the polishing pad 24 need not undergo a rotary motion and may move in one direction, for example, with a belt-like system.

Although there is no particular limitation on the polishing condition of such a polishing apparatus 20, if a load is exerted on the polishing head 22 to press the polishing head 22 against the polishing pad 24, the polishing pressure can be increased, and the polishing rate can thus be improved. The polishing pressure is preferably about 0.5 to 50 kPa, or is more preferably about 3 to 40 kPa from the standpoint of the uniformity of the polishing rate within the surface to be polished of the semiconductor substrate 21, the planarity, or the prevention of any polishing-induced defects, such as a scratch. The number of rotations of the polishing platen 23 and the polishing head 22 is preferably about 50 to 500 rpm. The amount of the polishing agent 25 to be fed is adjusted, as appropriate, based on the composition of the polishing agent or the polishing condition or the like described above.

For the polishing pad 24, a polishing pad made of nonwoven fabric, polyurethane foam, porous resin, nonporous resin, or the like can be used. In order to facilitate the feeding of the polishing agent to the polishing pad 24 or in order to pool a certain amount of the polishing agent 25 on the polishing pad 24, the surface of the polishing pad 24 may be grooved, for example, in a lattice pattern, in a concentric circular pattern, or in a spiral pattern. The polishing may be performed, as necessary, with a pad conditioner in contact with the surface of the polishing pad 24 and while the surface of the polishing pad 24 is conditioned.

The present polishing method makes it possible to obtain a high selectivity between a silicon oxide film and a silicon nitride film while inhibiting polishing-induced scratches and can achieve highly planar polishing.

The present invention will be described in concrete terms by way of examples and comparative examples below, but the present invention is not limited by these examples. Herein, Examples 1 to 4 and Examples 8 to 12 are working examples, and Examples 5 to 7 are comparative examples.

### [Method of Measurement]

<pH>

The pH was measured with the pH meter HM-30R manufactured by DKK-TOA CORPORATION with the temperature set to 25±5° C.

### <Mean Secondary Particle Size>

The mean secondary particle size was measured with a granularity distribution measuring apparatus of laser scattering/diffraction type (manufactured by HORIBA, Ltd., apparatus name: LA-950).

### <Aggregation Level of Abrasive Grains>

With a particle having a particle size of 1 μm or more regarded as a coarse particle, the number of coarse particles was measured three times with a number-counting granularity distribution measuring apparatus (manufactured by Nihon Entegris G.K., apparatus name: AccuSizer780) with the temperature set to 25 to 30° C., and the mean of these results was used as the number of coarse particles. Then, the ratio of this number of coarse particles to the number of coarse particles in the polishing agent of Example 1 was used as the aggregation level of the abrasive grains.

### <Acid Value>

The measurement was performed through the method described in JIS K 0070:1992.

### <Weight-Average Molecular Weight (Mw)>

The measurement was performed through gel permeation chromatography (GPC) under the following conditions:
Apparatus HLC-8320GPC (manufactured by Tosoh Corporation)
Column TSKgel GMPWXL (manufactured by Tosoh Corporation)
Detector RI detector polarity(+)
Eluent 0.2M-NaNO3 aqueous solution
flow rate 1.0 mL/min column temperature 40° C.
Calculated by conversion using standard PEO/PEG.

### <Selectivity>

The evaluation was performed with the fully automatic CMP apparatus FREX300X (manufactured by Ebara Corporation). A two-layer pad (IC-1570 manufactured by Rodel, Inc.) was used as a polishing pad, and a diamond pad conditioner (manufactured by 3M, product name: A165) was used to condition the polishing pad. The polishing conditions set were: polishing pressure of 21 kPa, the number of rotations of the polishing platen of 100 rpm, and the number of rotations of the polishing head of 102 rpm. The feeding rate of the polishing agent was 250 mL/min, unless specifically indicated otherwise.

The target for polishing used to evaluate the selectivity was a wafer having a silicon dioxide film in which the silicon dioxide film was deposited on a 12-inch silicon substrate through plasma CVD with tetraethoxysilane or monosilane used as a source material. Furthermore, a wafer having a silicon nitride film in which the silicon nitride film was deposited through CVD in a similar manner (this is referred to below as “blanket wafer”) was used.

Herein, the film thickness of the silicon dioxide film and the silicon nitride film deposited on a blanket wafer was measured with the membrane thickness gauge VM-3210 available from SCREEN Holdings. By obtaining the difference between the film thickness of the blanket wafer held before polishing and the film thickness held after the blanket wafer was polished for one minute, the polishing rate of the silicon dioxide film and the polishing rate of the silicon nitride film were each calculated. The mean (nm/min) of the polishing rates obtained from 49 points within the surface of the substrate was used as the polishing rate, and the ratio of the polishing rate of the silicon dioxide film to the polishing rate of the silicon nitride film (polishing rate of silicon dioxide film/polishing rate of silicon nitride film) was calculated as the selectivity.

### [Water-Soluble Polymer]

Water-soluble polymer A1: a copolymer that includes maleic acid ammonium salt (monomer (A)) and styrene (monomer (B)) at a ratio of 1:2 (mole ratio). The Mw is 8,000, the acid value is 350 mgKOH/g, and X is 1. Herein, “maleic acid ammonium salt” is a compound in which at least one of the two carboxy groups of maleic acid has become an ammonium salt (hereinafter, the same).

Water-soluble polymer A2: a copolymer that includes maleic acid ammonium salt (monomer (A)) and styrene (monomer (B)) at a ratio of 1:3 (mole ratio). The Mw is 10,000, the acid value is 275 mgKOH/g, and X is 1.

Water-soluble polymer A3: a copolymer that includes maleic acid ammonium salt and an ammonium salt of an ester derivative of maleic acid (monomer (A)) and styrene (monomer (B)) at a ratio of 1:2 (mole ratio). The Mw is 5,000 to 10,000, the acid value is 220 mgKOH/g, and X is 0.7. Herein, “ester derivative of maleic acid” is a compound in which at least one of the two carboxy groups of maleic acid has been esterified.

Water-soluble polymer B: a copolymer that includes maleic acid ammonium salt (monomer (A)) and styrene (monomer (B)) at a ratio of 1:1 (mole ratio). The Mw is 8,000, the acid value is 480 mgKOH/g, and X is 1.

Water-soluble polymer C: a copolymer that includes maleic acid monoester monoammonium salt (monomer (A)) and styrene (monomer (B)) at a ratio of 1:1 (mole ratio). Herein, the monomer (A) includes a small amount of maleic acid diester. The Mw is 7,000, the acid value is 180 mgKOH/g, and X is 0.4.

Water-soluble polymer D: a polyacrylic acid having Mw of 5,000 an acid value of about 780 mgKOH/g was used. X is 1.

### Example 1

Cerium oxide particles and ammonium polyacrylate, serving as a dispersant, having a molecular weight of 5,000 were mixed while being stirred with deionized water added thereto to achieve a mass ratio of 100:0.7, the resultant was subjected to ultrasonic dispersion and filtering to prepare a cerium oxide particle dispersion having a cerium oxide particle concentration of 10 mass % and a dispersant concentration of 0.07 mass %. Herein, the mean secondary particle size of the cerium oxide particles was 0.11 m.

Next, a water-soluble polymer A was added to deionized water to achieve a concentration of 0.005 mass % with respect to the total amount of the polishing agent, the cerium oxide particle dispersion above was added to the resultant to achieve a cerium oxide particle concentration of 0.25 mass % with respect to the total amount of the polishing agent, 2-hydroxyisobutyric acid was further added to the resultant to adjust the pH to 6.0, and thus a polishing agent (1) was obtained. Herein, the mean of the ceria content per particle of the cerium oxide particles above was 95 mass % or higher.

### Examples 2 to 7

Polishing agents (2) to (7) were obtained in a manner similar to that of Example 1, except that the water-soluble polymer, the pH regulator, and the target pH value were changed from those in Example 1 to the ones shown in Table 1.

The selectivity of the polishing agents (1) to (7) and the aggregation levels of the abrasive grains in the polishing agents obtained in Examples 1 to 7 were measured through the method described above. The results are shown in Table 1.

TABLE 1

| | | | Example 1 | Example 2 | Example 3 | Example 4 | Example 5 | Example 6 | Example 7 |
|---|---|---|---|---|---|---|---|---|---|
| Polishing | Water- | Type | A1 | A1 | A2 | A3 | B | C | D |
| Agent | Soluble | Mw [g/mol] | 8000 | 8000 | 10000 | 5000-10000 | 8000 | 7000 | 5000 |
| | Polymer | X | 1 | 1 | 1 | 0.7 | 1 | 0.4 | 1 |

| | pH Regulator | 2- | succinic | maleic | adipic | 2- | 2- | monoethanol- |
|---|---|---|---|---|---|---|---|---|
| | | hydroxyiso- | acid | acid | acid | hydroxyiso- | hydroxyiso- | amine |
| | | butyric | | | | butyric | butyric | |
| | | acid | | | | acid | acid | |
| | pH | 6 | 5.8 | 5.8 | 5.8 | 6 | 7.4 | 6 |
| Evaluation | Selectivity | 53 | 58 | 100 | 46 | 17 | 45 | 16 |
| | Number of | 1 | 0.6 | 1.3 | 1.6 | 0.6 | 3 | 1.6 |
| | Coarse Particles | | | | | | | |
| | (Ratio to | | | | | | | |
| | Example 1) | | | | | | | |

The polishing agents of Example 5 and Example 7 that used, respectively, the polymer B and the polymer D having a high acid value as water-soluble polymers had a low selectivity of 20 or lower, although the numbers of coarse particles were kept low. Meanwhile, the polishing agent of Example 6 that used the polymer C having a high acid value as a water-soluble polymer had more than twice the number of coarse particles of the polishing agent of Example 1 and was recognized to have aggregation of abrasive grains. In contrast, the polishing agents of Examples 1 to 4 that used water-soluble polymers having an acid value of 200 to 450 mgKOH/g were shown to have achieved a high selectivity (e.g., 20 or higher) and to have inhibited abrasive grain aggregation (e.g., the numbers of coarse particles were 2 or lower). In this manner, the polishing agent according to the present invention that uses a water-soluble polymer that is a copolymer of a monomer (A) and a monomer (B) other than the monomer (A) and that has an acid value of 200 to 450 mgKOH/g is shown to have a high selectivity between a silicon oxide film and a silicon nitride film and to inhibit aggregation of abrasive grains that can cause polishing-induced scratches.

### Examples 8 to 12

Polishing agents (8) to (12) were obtained in a manner similar to that of Example 1, except that the type of the pH regulator in Example 1 was changed to those shown in Table 2.

The polishing rate of a silicon dioxide film (Ox rate) by and the selectivity of the polishing agent (1) and the polishing agents (8) to (12) obtained in Example 1 and Examples 8 to 12 were measured through the method described above. The results are shown in Table 2. Herein, “selectivity” in Table 2 shows the value of the ratio with respect to the selectivity of Example 12.

TABLE 2

| | | Example 1 | Example 8 | Example 9 | Example 10 | Example 11 | Example 12 |
|---|---|---|---|---|---|---|---|
| Polishing | Water-Soluble | A1 | A1 | A1 | A1 | A1 | A1 |
| Agent | Polymer | | | | | | |
| | pH Regulator | 2- | succinic | maleic | picolinic | adipic | citric |
| | | hydroxyiso- | acid | acid | acid | acid | acid |
| | | butyric | | | | | |
| | | acid | | | | | |
| | pH | 6 | 6 | 6 | 6 | 6 | 6 |
| Evaluation | Ox Rate | 2000 | 2300 | 1800 | 1400 | 2100 | 1500 |
| | Selectivity | 1.2 | 1.6 | 1.7 | 1.2 | 1.7 | 1 |

The polishing agents of Example 1 and Examples 8 to 12, in which an organic acid was used as a pH regulator, all excelled in the polishing rate of a silicon dioxide film and had a high selectivity. In particular, the polishing agents of Examples 8 to 11, in which the organic acid was a monocarboxylic acid or a dicarboxylic acid, showed an even higher selectivity.

### INDUSTRIAL APPLICABILITY

According to the present invention, a high selectivity between a silicon oxide film and a silicon nitride film can be achieved, for example, in CMP of a surface to be polished that includes a silicon oxide while inhibiting polishing-induced scratches. Accordingly, the polishing agent and the polishing method according to the present invention are suitable for planarization of insulating films for STI in semiconductor device manufacturing.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing agent comprising:
an abrasive grain;
a water-soluble polymer; and
water, wherein
the water-soluble polymer is a copolymer of a monomer (A) that is at least one selected from an unsaturated dicarboxylic acid, a derivative thereof, and salts thereof, and a monomer (B) other than the monomer (A),
the monomer (B) is a monomer that includes an ethylenic double bond and does not include an acidic group, and
the water-soluble polymer has an acid value of 200 to 450 mgKOH/g.

2. The polishing agent according to claim 1, wherein
X obtained through formula (1) below is 0.5 or higher:
$$X = ( the number of COOH and {COO}^{-} in the water - soluble polymer above ) / ( the number of COOH , {COO}^{-} and COR in the water - soluble polymer above ) \qquad ( 1 )$$
wherein, R is a substituent.

3. The polishing agent according to claim 1, wherein the monomer (A) is at least one selected from an unsaturated dicarboxylic acid and a salt thereof.

4. The polishing agent according to claim 1, further comprising a pH regulator.

5. The polishing agent according to claim 4, wherein the pH regulator includes an acid.

6. The polishing agent according to claim 5, wherein the acid includes an organic acid having 1 to 2 carboxy groups.

7. The polishing agent according to claim 6, wherein the organic acid includes at least one selected from acetic acid, gluconic acid, lactic acid, picolinic acid, malic acid, oxalic acid, succinic acid, adipic acid, maleic acid, 2-hydroxyisobutyric acid, 2-bis(hydroxymethyl)propionic acid, and 2-bis(hydroxymethyl)butyric acid.

8. The polishing agent according to claim 1, wherein the unsaturated dicarboxylic acid includes at least one selected from maleic acid, itaconic acid, and fumaric acid.

9. The polishing agent according to claim 1, wherein the monomer (B) includes at least one selected from a monomer having a ring structure and an olefin having a carbon number of 3 to 7.

10. The polishing agent according to claim 9, wherein the monomer (B) includes at least one selected from styrene, N-vinylpyrrolidone, 4-vinylpyridine, and isobutylene.

11. The polishing agent according to claim 9, wherein the monomer (B) includes styrene or isobutylene.

12. The polishing agent according to claim 1, wherein the water-soluble polymer has a weight-average molecular weight of 10,000 or less.

13. The polishing agent according to claim 1, wherein pH is 5 to 8.

14. A liquid additive for a polishing agent, the liquid additive comprising:
a water-soluble polymer; and
water, wherein
the water-soluble polymer is a copolymer of a monomer (A) that is at least one selected from an unsaturated dicarboxylic acid, a derivative thereof, and salts thereof, and a monomer (B) other than the monomer (A),
the monomer (B) is a monomer that includes an ethylenic double bond and does not include an acidic group, and
the water-soluble polymer has an acid value of 200 to 450 mgKOH/g.

15. A polishing method of bringing a surface to be polished and a polishing pad into contact while a polishing agent is fed thereto and of performing polishing through relative motions of the surface to be polished and the polishing pad, the polishing method comprising:
polishing a surface to be polished that includes a silicon oxide of a semiconductor substrate by using the polishing agent according to claim 1 as the polishing agent.
